(19) United States
(12) Patent Application Publication
(10) Pub. No.: US 2015/0293449 A1
(43) Pub. Date: Oct. 15, 2015

(54) PHOTOSENSITIVE POLYSILOXANE COMPOSITION AND USES THEREOF

(71) Applicant: CHI MEI CORPORATION, Tainan City (TW)

(72) Inventors: MING-JU WU, TAINAN CITY (TW); CHUN-AN SHIH, TAINAN CITY (TW)

(21) Appl. No.: 14/751,705

(22) Filed: Jun. 26, 2015

Related U.S. Application Data
(63) Continuation-in-part of application No. 14/448,645, filed on Jul. 31, 2014.

(30) Foreign Application Priority Data
Aug. 13, 2013 (TW) 102128929
Sep. 25, 2014 (TW) 103133339

(51) Int. Cl. G03F 7/075

(52) U.S. Cl. CPC G03F 7/0757

(57) ABSTRACT

The invention relates to a photosensitive polysiloxane composition and a thin film formed by the aforementioned photosensitive polysiloxane composition. The thin film is a planarization film of a TFT substrate, an interlayer insulating film or an overcoat of a core material or a protective material in a waveguide. The thin film is cured at low temperature. The photosensitive polysiloxane composition comprises a polysiloxane (A), an o-naphthoquinone diazide sulfonic acid ester (B), a thermal base generator (C) and a solvent (D).

### BACKGROUND OF THE INVENTION

1. Field of the Invention

The invention relates to a photosensitive polysiloxane composition for forming a planarization film of a TFT substrate in a liquid crystal display element or organic light-emitting display device, an interlayer insulating film or an overcoat of a core material or a protective material in a waveguide. The invention also relates to a thin film formed by the aforementioned photosensitive polysiloxane composition and a device comprising the thin film. More particularly, the invention is to provide a photosensitive polysiloxane composition cured at low temperature after exposing and developing.

2. Description of the Related Art

In recent years, in the field of the semiconductor industry, liquid crystal displays (LCDs) and organic electro-luminescence displays (OELDs), with the size reduction; the demand of the miniaturization of the pattern(s) in the photolithography process is increased. Generally, the miniaturized pattern is formed by exposing and developing a positive photosensitive composition having high resolution and high photosensitivity; wherein, a positive photosensitive composition using a polysiloxane as the main component has become the mainstream in this field.

In the liquid crystal displays or organic electro-luminescence displays, an interlayered insulating film is usually equipped between layered wires for insulating. Because the number of necessary steps for a photosensitive material to form a pattern is less; moreover, an insulating film obtained thereof has good flatness, the photosensitive material is widely used in forming the interlayered insulating film.

For example, forming a pattern for a tiny wiring contact hole is essential to the interlayered insulating film used in the liquid crystal display. In fact, an aperture of the contact hole formed by a negative photosensitive composition is difficult to meet the practical requirement. Therefore, a positive photosensitive composition is widely used in this field to form the interlayered insulating film in the liquid crystal display (Japanese Patent Publication No. 2001-354822).

Generally, a main component of the photosensitive composition for forming the interlayer insulating film is acrylic acid resins. However, a photosensitive composition having a siloxane material has better heat resistance and transparency than that having acrylic acid resins (Japanese Patent Publication No. 2000-1648).

However, because the siloxane material such as silane or polysiloxane is easy to carry out hydrolysis and condensation reaction with similar or dissimilar compounds, the storage stability of the photosensitive composition prepared with the siloxane material is unsatisfactory and the lifespan of the products formed therefrom is also shortened.

To inhibit the aforementioned reaction, controlling molecular weights and branch structures of the polysiloxane is developed. Japanese Patent Publication No. 2003-163209 discloses polysiloxanes with different molecular weights obtained by controlling the structure in the presence of an acid catalyst, a metal chelator and a base catalyst. However, although the aforementioned patent discloses the polysiloxanes with different molecular weights, the photosensitive property of the polysiloxanes is not considered and properties of the interlayer insulating film except dielectric constant are not considered, either.

In the situation, Japanese Patent Publication No. 2011-123450 discloses a positive photosensitive polysiloxane composition has excellent photosensitivity, storage stability and melts floating resistance. However, the hardness of the positive photosensitive polysiloxane composition cured at low temperature is insufficient, so it cannot be accepted in the industry.

Therefore, improving the property of the photosensitive polysiloxane composition cured at low temperature in order to meet the modern requirements is a target remained to be achieved.

### SUMMARY OF THE INVENTION

In the present invention, a specific polysiloxane and thermal base generator are provided to obtain a photosensitive polysiloxane composition cured at low temperature.

Therefore, the invention relates to a photosensitive polysiloxane composition comprising:
a polysiloxane (A);
an o-naphthoquinone diazide sulfonic acid ester (B);
a thermal base generator (C); and
a solvent (D);
wherein
the polysiloxane (A) is a copolymer obtained by hydrolyzing and partial condensing a mixture comprising a silane monomer (a-1) represented by Formula (1), a silane monomer (a-2) represented by Formula (2) and a silane monomer (a-3) represented by Formula (3):

Si(Rₐ)_{W}(OR_{b})_{4-w} Formula (1),
wherein:
Rₐ represents a hydrogen atom, a C₁-C₁₀ alkyl group, a C₂-C₁₀ alkenyl group, a C₆-C₁₅ aryl group, an alkyl group having an acid anhydride group, an alkyl group having an epoxy group, or an alkoxy group having an epoxy group;
at least one of Rₐ represents the alkyl group having the acid anhydride group;
R_{b} represents a hydrogen atom, a C₁-C₆ alkyl group, a C₁-C₆ acyl group, or a C₆-C₁₅ aryl group; and
w represents an integer of 1 to 3; when w represents 2 to 3, each Rₐ is the same or different; when w represents 1 to 2, each R_{b} is the same or different;

Si(R_{c})ᵥ(OR_{d})₄₋ᵥ Formula(2),
wherein:
R_{c} represents a hydrogen atom, a C₁-C₁₀ alkyl group, a C₂-C₁₀ alkenyl group, a C₆-C₁₅ aryl group, an alkyl group having an acid anhydride group, an alkyl group having an epoxy group, or an alkoxy group having an epoxy group;

at least one of R_{c} represents the alkyl group having the epoxy group or the alkoxy group having the epoxy group;

R_{d} represents a hydrogen atom, a C₁-C₆ alkyl group, a C₁-C₆ acyl group, or a C₆-C₁₅ aryl group; and
v represents an integer of 1 to 3; when v represents 2 to 3, each R_{c} is the same or different; when v represents 1 to 2, each R_{d} is the same or different;

Si(Rₑ)ᵤ(OR_{f})₄₋ᵤ Formula (3),
wherein:
Rₑ represents a hydrogen atom, a C₁-C₁₀ alkyl group, a C₂-C₁₀ alkenyl group, a C₆-C₁₅ aryl group;

R_{f} represents a hydrogen atom, a C₁-C₆ alkyl group, a C₁-C₆ acyl group, or a C₆-C₁₅ aryl group; and

u represents an integer of 0 to 3; when u represents 2 to 3, each Rₑ is the same or different; when u represents 0 to 2, each R_{f} is the same or different;

the thermal base generator (C) comprises a compound represented by Formula (4) or an salt derivative thereof and/or a compound represented by Formula (5) and/or a compound represented by Formula (6):

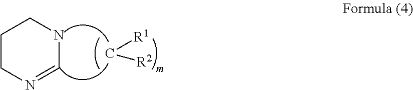

wherein:
m represents an integer of 2 to 6;
R¹ and R² independently represent a hydrogen atom, a C₁-C₈ alkyl group, a substituted or unsubstituted C₁-C₆ hydroxyalkyl group, or a C₂-C₁₂ dialkylamino group;

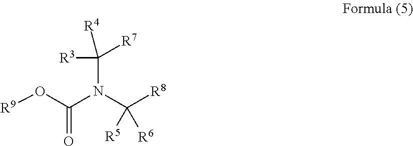

wherein:
R³, R⁴, R⁵ and R⁶ independently represent a hydrogen atom, a substituted or unsubstituted C₁-C₈ alkyl group, a substituted or unsubstituted C₃-C₈ cycloalkyl group, a substituted or unsubstituted C₁-C₈ alkoxy group, a substituted or unsubstituted C₂-C₈ alkenyl group, a substituted or unsubstituted C₂-C₈ alkynyl group, a substituted or unsubstituted aryl group, or a substituted or unsubstituted heterocyclic group;
R⁷ and R⁸ independently represent a hydrogen atom, a substituted or unsubstituted C₁-C₈ alkyl group, a substituted or unsubstituted C₃-C₈ cycloalkyl group, a substituted or unsubstituted C₁-C₈ alkoxy group, a substituted or unsubstituted C₂-C₈ alkenyl group, a substituted or unsubstituted C₂-C₈ alkynyl group, a substituted or unsubstituted aryl group, or a substituted or unsubstituted heterocyclic group, or R⁷ and R⁸ together form a substituted or unsubstituted monocyclic group, or R⁷ and R⁸ together form a substituted or unsubstituted polycyclic group;
R⁹ represents a substituted or unsubstituted C₁-C₁₂ alkyl group, a substituted or unsubstituted C₃-C₁₂ cycloalkyl group, a substituted or unsubstituted C₂-C₁₂ alkenyl group, a substituted or unsubstituted C₂-C₁₂ alkynyl group, an unsubstituted aryl group, an aryl group substituted with a C₁-C₃ alkyl group, an unsubstituted aralkyl, an aralkyl group substituted with a C₁-C₃ alkyl group or a substituted or unsubstituted heterocyclic group; the total carbon atom amount of R⁹ is below 12;

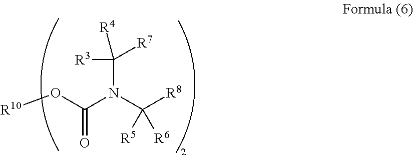

wherein:
R³, R⁴, R⁵, R⁶, R⁷ and R⁸ are as defined in Formula (5);
R¹⁰ represents a substituted or unsubstituted C₁-C₁₂ alkylene group, a substituted or unsubstituted C₃-C₁₂ cycloalkylene group, a substituted or unsubstituted C₂-C₁₂ alkenylene group, a substituted or unsubstituted C₂-C₁₂ alkynylene group, an unsubstituted arylene group, an arylene group substituted with a C₁-C₃ alkyl group, an unsubstituted aralkylene group, an aralkylene group substituted with a C₁-C₃ alkyl group or a substituted or unsubstituted heterocyclic group; the total carbon atom amount of R¹⁰ is below 12.

The present invention also provides a method for forming a thin film on a substrate comprising applying the photosensitive polysiloxane composition as mentioned above on the substrate.

The present invention also provides a thin film on a substrate, which is manufactured by the method as mentioned above.

The present invention further provides a device comprising the thin film as mentioned above.

### DETAILED DESCRIPTION OF THE INVENTION

The invention provides a photosensitive polysiloxane composition comprising:
a polysiloxane (A);
an o-naphthoquinone diazide sulfonic acid ester (B);
a thermal base generator (C); and
a solvent (D);
wherein
the polysiloxane (A) is a copolymer obtained by hydrolyzing and partial condensing a mixture comprising a silane monomer (a-1) represented by Formula (1), a silane monomer (a-2) represented by Formula (2) and a silane monomer (a-3) represented by Formula (3):

Si(Rₐ)_{w}(OR_{b})_{4-w} Formula (1),
wherein:
Rₐ represents a hydrogen atom, a C₁-C₁₀ alkyl group, a C₂-C₁₀ alkenyl group, a C₆-C₁₅ aryl group, an alkyl group having an acid anhydride group, an alkyl group having an epoxy group, or an alkoxy group having an epoxy group;
at least one of Rₐ represents the alkyl group having the acid anhydride group;
R_{b} represents a hydrogen atom, a C₁-C₆ alkyl group, a C₁-C₆ acyl group, or a C₆-C₁₅ aryl group; and
w represents an integer of 1 to 3; when w represents 2 to 3, each Rₐ is the same or different; when w represents 1 to 2, each R_{b} is the same or different;

Si(R_{c})ᵥ(OR_{d})₄₋ᵥ Formula (2),
wherein:
R_{c} represents a hydrogen atom, a C₁-C₁₀ alkyl group, a C₂-C₁₀ alkenyl group, a C₆-C₁₅ aryl group, an alkyl group having an acid anhydride group, an alkyl group having an epoxy group, or an alkoxy group having an epoxy group;
at least one of Rₑ represents the alkyl group having the epoxy group or the alkoxy group having the epoxy group;
R_{d} represents a hydrogen atom, a C₁-C₆ alkyl group, a C₁-C₆ acyl group, or a C₆-C₁₅ aryl group; and
v represents an integer of 1 to 3; when v represents 2 to 3, each R_{c} is the same or different; when v represents 1 to 2, each R_{d} is the same or different;

Si(Rₑ)ᵤ(OR_{f})₄₋ᵤ Formula (3),
wherein:
Rₑ represents a hydrogen atom, a C₁-C₁₀ alkyl group, a C₂-C₁₀ alkenyl group, a C₆-C₁₅ aryl group;
R_{f} represents a hydrogen atom, a C₁-C₆ alkyl group, a C₁-C₆ acyl group, or a C₆-C₁₅ aryl group; and
u represents an integer of 0 to 3; when u represents 2 to 3, each Rₑ is the same or different; when u represents 0 to 2, each R_{f} is the same or different;
the thermal base generator (C) comprises a compound represented by Formula (4) or an salt derivative thereof and/or a compound represented by Formula (5) and/or a compound represented by Formula (6):

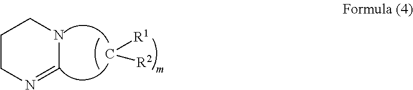

wherein:
m represents an integer of 2 to 6;
R¹ and R² independently represent a hydrogen atom, a C₁-C₈ alkyl group, a substituted or unsubstituted C₁-C₆ hydroxyalkyl group, or a C₂-C₁₂ dialkylamino group;

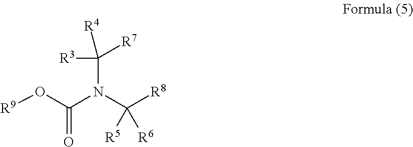

wherein:
R³, R⁴, R⁵ and R⁶ independently represent a hydrogen atom, a substituted or unsubstituted C₁-C₈ alkyl group, a substituted or unsubstituted C₃-C₈ cycloalkyl group, a substituted or unsubstituted C₁-C₈ alkoxy group, a substituted or unsubstituted C₂-C₈ alkenyl group, a substituted or unsubstituted C₂-C₈ alkynyl group, a substituted or unsubstituted aryl group, or a substituted or unsubstituted heterocyclic group;
R⁷ and R⁸ independently represent a hydrogen atom, a substituted or unsubstituted C₁-C₈ alkyl group, a substituted or unsubstituted C₃-C₈ cycloalkyl group, a substituted or unsubstituted C₁-C₈ alkoxy group, a substituted or unsubstituted C₂-C₈ alkenyl group, a substituted or unsubstituted C₂-C₈ alkynyl group, a substituted or unsubstituted aryl group, or a substituted or unsubstituted heterocyclic group, or R⁷ and R⁸ together form a substituted or unsubstituted monocyclic group, or R⁷ and R⁸ together form a substituted or unsubstituted polycyclic group;
R⁹ represents a substituted or unsubstituted C₁-C₁₂ alkyl group, a substituted or unsubstituted C₃-C₁₂ cycloalkyl group, a substituted or unsubstituted C₂-C₁₂ alkenyl group, a substituted or unsubstituted C₂-C₁₂ alkynyl group, an unsubstituted aryl group, an aryl group substituted with a C₁-C₃ alkyl group, an unsubstituted aralkyl, an aralkyl group substituted with a C₁-C₃ alkyl group or a substituted or unsubstituted heterocyclic group; the total carbon atom amount of R⁹ is below 12;

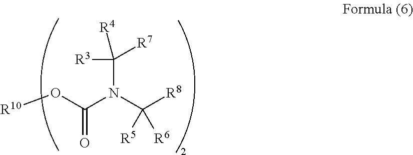

wherein:
R³, R⁴, R⁵, R⁶, R⁷ and R⁸ are as defined in Formula (5);
R¹⁰ represents a substituted or unsubstituted C₁-C₁₂ alkylene group, a substituted or unsubstituted C₃-C₁₂ cycloalkylene group, a substituted or unsubstituted C₂-C₁₂ alkenylene group, a substituted or unsubstituted C₂-C₁₂ alkynylene group, an unsubstituted arylene group, an arylene group substituted with a C₁-C₃ alkyl group, an unsubstituted aralkylene group, an aralkylene group substituted with a C₁-C₃ alkyl group or a substituted or unsubstituted heterocyclic group; the total carbon atom amount of R¹⁰ is below 12.

The polysiloxane (A) is a copolymer obtained by hydrolyzing and partial condensing a mixture comprising a silane monomer (a-1) represented by Formula (1), a silane monomer (a-2) represented by Formula (2) and a silane monomer (a-3) represented by Formula (3).

Si(Rₐ)_{w}(OR_{b})_{4-w} Formula (1),

In Formula (1), Rₐ represents a hydrogen atom, a C₁-C₁₀ alkyl group, a C₂-C₁₀ alkenyl group, a C₆-C₁₅ aryl group, an alkyl group having an acid anhydride group, an alkyl group having an epoxy group, or an alkoxy group having an epoxy group;
at least one of Rₐ represents the alkyl group having the acid anhydride group;
R_{b} represents a hydrogen atom, a C₁-C₆ alkyl group, a C₁-C₆ acyl group, or a C₆-C₁₅ aryl group; and
w represents an integer of 1 to 3; when w represents 2 to 3, each Rₐ is the same or different; when w represents 1 to 2, each R_{b} is the same or different.

Preferably, the alkyl group having the acid anhydride group is a C₁-C₁₀ alkyl group having the acid anhydride group; for example, is ethyl succinic anhydride, propyl succinic anhydride or propyl glutaric anhydride.

Preferably, the alkyl group having the epoxy group is a C₁-C₁₀ alkyl group having the epoxy group; for example, is oxetanylpentyl or 2-(3,4-epoxycyclohexyl)ethyl).

The alkoxy group having the epoxy group, for example, is glycidoxypropy or 2-oxetanylbutoxy.

In the definition of R_{b}, the C₁-C₆ alkyl group includes but is not limited to methyl, ethyl, n-propyl, isopropyl or n-butyl. The C₁-C₆ acyl group includes but is not limited to acetyl. The C₆-C₁₅ aryl group includes but is not limited to phenyl.

The silane monomer (a-1) represented by Formula (1) can be used singly or in combination, and the silane monomer (a-1) represented by Formula (1) includes but is not limited to 3-triphenoxysilyl propyl succinic anhydride, the commercially available products from Shin-Etsu Chemical Co., Ltd.: 3-trimethoxysilyl propyl succinic anhydride (trade name: X-12-967), the commercially available products from WACKER Co., Ltd: 3-(triethoxysilyl) propyl succinic anhydride (trade name: GF-20), 3-(trimethoxysilyl) propyl glutaric anhydride (abbreviated as TMSG), 3-(triethoxysilyl) propyl glutaric anhydride, 3-(triphenoxysilyl) propyl glutaric anhydride, (di-n-butoxysilyl)di(propyl succinic anhydride), (dimethoxysilyl)di(ethyl succinic anhydride), (phenoxysilyl)tri(propyl succinic anhydride) or (methoxysilyl)di(ethyl succinic anhydride).

Based on 1 mole of the total used amount of the monomers in the mixture, the used amount of the silane monomer (a-1) is from 0.01 moles to 0.2 moles; preferably 0.02 moles to 0.18 moles; and more preferably 0.03 moles to 0.15 moles. If the silane monomer (a-1) is absent in the polysiloxane (A) according to the invention (i.e. if the polysiloxane (A) does not have the alkyl group having the acid anhydride group), the photosensitive polysiloxane composition is not cured well at low temperature.

The silane monomer (a-2) represented by Formula (2) is shown as the following:

Si(R_{c})ᵥ(OR_{d})₄₋ᵥ Formula(2),
wherein:
R_{c} represents a hydrogen atom, a C₁-C₁₀ alkyl group, a C₂-C₁₀ alkenyl group, a C₆-C₁₅ aryl group, an alkyl group having an acid anhydride group, an alkyl group having an epoxy group, or an alkoxy group having an epoxy group;
at least one of R_{c} represents the alkyl group having the epoxy group or the alkoxy group having the epoxy group;

R_{d} represents a hydrogen atom, a C₁-C₆ alkyl group, a C₁-C₆ acyl group, or a C₆-C₁₅ aryl group; and
v represents an integer of 1 to 3; when v represents 2 to 3, each R_{c} is the same or different; when v represents 1 to 2, each R_{d} is the same or different.

Preferably, the alkyl group having the acid anhydride group is a C₁-C₁₀ alkyl group having the acid anhydride group; for example, is ethyl succinic anhydride, propyl succinic anhydride or propyl glutaric anhydride.

Preferably, the alkyl group having the epoxy group is a C₁-C₁₀ alkyl group having the epoxy group; for example, is oxetanylpentyl or 2-(3,4-epoxycyclohexyl)ethyl).

The alkoxy group having the epoxy group; for example, is glycidoxypropy or 2-oxetanylbutoxy.

In the definition of R_{d}, the C₁-C₆ alkyl group includes but is not limited to methyl, ethyl, n-propyl, isopropyl or n-butyl. The C₁-C₆ acyl group includes but is not limited to acetyl. The C₆-C₁₅ aryl group includes but is not limited to phenyl.

The silane monomer (a-2) represented by Formula (2) can be used singly or in combination, and the silane monomer (a-2) represented by Formula (2) includes but is not limited to 3-glycidoxypropyltrimethoxysilane (abbreviated as TMS-GAA), 3-glycidoxypropyltriethoxysilane, 2-(3,4-epoxycyclohexyl)ethyl trimethoxy silane, 2-oxetanylbutoxypropyltriphenoxysilane), the commercially available products from Toagosei Co., Ltd.: 2-oxetanylbutoxypropyltrimethoxysilane (trade name: TMSOX-D), 2-oxetanylbutoxypropyltriethoxysilane (trade name: TESOX-D), the commercially available products from WACKER Co., Ltd: diisopropoxy-di(2-oxetanylbutoxy propyl) silane (abbreviated as DIDOS), di(3-oxetanylpentyl)dimethoxy silane, 3-glycidoxypropyldimethylmethoxysilane, 3-glycidoxypropyldimethylethoxysilane, di(2-oxetanylbutoxypentyl)-2-oxetanylpentylethoxy silane, or tri(2-oxetanylpentyl)methoxy silane.

Based on 1 mole of the total used amount of the monomers in the mixture, the used amount of the silane monomer (a-2) is from 0.01 moles to 0.4 moles; preferably 0.02 moles to 0.35 moles; and more preferably 0.03 moles to 0.3 moles. If the silane monomer (a-2) is absent in the polysiloxane (A) according to the invention (i.e. if the polysiloxane (A) does not have the alkyl group having the epoxy group), the photosensitive polysiloxane composition is not cured well at low temperature. Though not willing to be limited by theory, it is believed that because the polysiloxane (A) needs the epoxy group to carry out a further reaction to improve the curing at low temperature.

The silane monomer (a-3) represented by Formula (3) is shown as the following:

Si(Rₑ)ᵤ(OR_{f})₄₋ᵤ Formula (3),
wherein:
Rₑ represents a hydrogen atom, a C₁-C₁₀ alkyl group, a C₂-C₁₀ alkenyl group, a C₆-C₁₅ aryl group;
R_{f} represents a hydrogen atom, a C₁-C₆ alkyl group, a C₁-C₆ acyl group, or a C₆-C₁₅ aryl group; and
u represents an integer of 0 to 3; when u represents 2 to 3, each Rₑ is the same or different; when u represents 0 to 2, each R_{f} is the same or different.

In the definition of Rₑ, the C₁-C₁₀ alkyl group, for example, is methyl, ethyl, n-propyl, isopropyl, n-butyl, tertiary butyl, n-hexyl, n-decyl, trifluoromethyl, 3,3,3-trifluoro-propyl, 3-aminopropyl, 3-mercaptopropyl or 3-isocyanatepropyl. The C₂-C₁₀ alkenyl group, for example, is vinyl, 3-acryloxypropyl or 3-methacryloxypropyl. The C₆-C₁₅ aryl group, for example, is phenyl, tolyl, o-hydroxyphenyl, 1-(o-hydroxyphenyl)ethyl, 2-(o-hydroxyphenyl)ethyl, 4-hydroxy-5-(p-hydroxyphenylcarbonyloxy) pentyl or naphthyl.

In the definition of R_{f}, the C₁-C₆ alkyl group, for example, is methyl, ethyl, n-propyl, isopropyl, or n-butyl. The C₁-C₆ acyl group, for example, is acetyl. The C₆-C₁₅ aryl group, for example, is phenyl.

The silane monomer (a-3) represented by Formula (3) can be used singly or in combination, and the silane monomer (a-3) represented by Formula (3) includes but is not limited to tetramethoxysilane, tetraethoxysilane, tetraacetoxysilane, tetraphenoxy silane, methyltrimethoxysilane (abbreviated as MTMS), methyltriethoxysilane, methyltriisopropoxysilane, methyltri-n-butoxysilane, ethyltrimethoxysilane, ethyltriethoxysilane, ethyltriisopropoxysilane, ethyltri-n-butoxysilane, n-propyltrimethoxysilane, n-propyltriethoxysilane, n-butyltrimethoxysilane, n-butyltriethoxysilane, n-hexyltrimethoxysilane, n-hexyltriethoxysilane, decyltrimethoxysilane, vinyltrimethoxysilane, vinyltriethoxysilane, phenyltrimethoxysilane (abbreviated as PTMS), phenyltriethoxysilane (abbreviated as PTES), p-hydroxyphenyltrimethoxysilane, 1-(p-hydroxyphenyl)ethyltrimethoxysilane, 2-(p-hydroxyphenyl)ethyltrimethoxysilane, 4-hydroxy-5-(p-hydroxyphenylcarbonyloxy)pentyltrimethoxysilane, trifluoromethyltrimethoxysilane, trifluoromethyltriethoxysilane, 3,3,3-trifluoropropyltrimethoxysilane, 3-aminopropyltrimethoxysilane, 3-aminopropyltriethoxysilane, dimethyldimethoxysilane (abbreviated as DMDMS), dimethyldiethoxysilane, dimethyldiacetyloxysilane, di-n-butyldimethoxysilane, diphenyldimethoxysilane, trimethylmethoxysilane, tri-n-butylethoxysilane, 3-mercaptopropyltrimethoxysilane, 3-acryloxypropyltrimethoxysilane, 3-methacryloyloxypropyltrimethoxysilane, or 3-methacryloyloxypropyltriethoxysilane.

Based on 1 mole of the total used amount of the monomers in the mixture, the used amount of the silane monomer (a-3) is from 0.4 moles to 0.98 moles; preferably 0.47 moles to 0.96 moles; and more preferably 0.55 moles to 0.94 moles.

Preferably, the silane monomer (a-3) represented by Formula (3) further comprises a silane monomer (a-3-1) represented by Formula (i) shown as the following:

Si(OR_{g})₄ Formula (i),
wherein:
R_{g} represents a hydrogen atom, a C₁-C₆ alkyl group, a C₁-C₆ acyl group, or a C₆-C₁₅ aryl group; and each R_{g} is the same or different.

It is noted that any one of the above alkyl group, acyl group and aryl group can have a substituent. In the definition of R_{g}, the C₁-C₆ alkyl group, for example, is methyl, ethyl, n-propyl, isopropyl, or n-butyl. The C₁-C₆ acyl group, for example, is acetyl. The C₆-C₁₅ aryl group, for example, is phenyl.

The silane monomer (a-3-1) represented by Formula (i) can be used singly or in combination, and the silane monomer (a-3-1) represented by Formula (i) includes but is not limited to tetramethoxysilane, tetraethoxysilane, tetraacetoxysilane, or tetraphenoxy silane.

Based on 1 mole of the total used amount of the monomers in the mixture, the used amount of the silane monomer (a-3-1) represented by Formula (i) is from 0.1 moles to 0.6 moles; preferably 0.1 moles to 0.55 moles; and more preferably 0.15 moles to 0.55 moles. If the used amount of the silane monomer (a-3-1) represented by Formula (i) is from 0.1 moles to 0.6 moles, the photosensitive polysiloxane composition is cured well at low temperature.

Preferably, the mixture also comprises an other polysiloxane represented by Formula (ii):

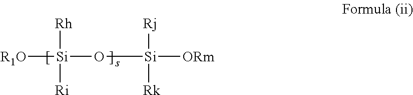

In Formula (ii), each Rₕ, Rᵢ, Rⱼ and Rₖ are the same or different, and each independently represents a hydrogen atom, a C₁-C₁₀ alkyl group, a C₂-C₆ alkenyl group, or a C₆-C₁₅ aryl group. It is noted that any one of the above alkyl group, alkenyl group and aryl group can optionally have a substituent. When s is an integer from 2 to 1000, each Rₕ is the same or different, and Rᵢ is the same or different. The alkyl group, for example, is methyl, ethyl or n-propyl; the alkenyl group, for example, is vinyl, acryloyl-propyl or methyl-acryloyloxy-propy; the aryl group, for example, is phenyl, tolyl, or naphthyl.

Rₗ, and Rₘ independently represent a hydrogen atom, a C₁-C₆ alkyl group, a C₁-C₆ acyl group, or a C₆-C₁₅ aryl group. It is noted that any one of the above alkyl group, acyl group and aryl group can optionally have a substituent. The alkyl group, for example, is methyl, ethyl, n-propyl, isopropyl, or n-butyl.; the acyl group, for example, is acetyl; the aryl group, for example, is phenyl.

In Formula (ii), s is an integer selected from 1 to 1000; preferably s is an integer selected from 3 to 300; more preferably s is an integer selected from 5 to 200.

The other polysiloxane represented by Formula (ii) can be used singly or in combination. The other polysiloxane represented by Formula (ii) includes but is not limited to 1,1,3,3-tetramethyl-1,3-dimethoxy disiloxane, 1,1,3,3-tetramethyl-1,3-diethoxy disiloxane, 1,1,3,3-tetraethyl-1,3-diethoxy disiloxane or the commercially available products of silanol terminated polydimethylsiloxane manufactured by Gelest Company (trade names such as DM-S12 (molecular weight of 400 to 700), DMS-S15 (molecular weight of 1500 to 2000), DMS-S21 (molecular weight 4200), DMS-S27 (molecular weight 18000), DMS-S31 (molecular weight 26000), DMS-S32 (molecular weight 36000), DMS-S33 (molecular weight 43500), DMS-S35 (molecular weight 49000), DMS-S38 (MW 58000) DMS-S42 (molecular weight 77000) or PDS-9931 (MW 1000-1400)).

Preferably, the mixture also includes silicon dioxide particles. The average particle diameter of the silicon dioxide particles is not particularly limited and ranges from 2 nm to 250 nm, preferably from 5 nm to 200 nm, and more preferably from 10 nm to 100 nm.

The silicon dioxide particles can be used singly or in combination, and the silicon dioxide particles include but are not imited to commercially available products manufactured by Jgc Catalysts & Chemicals Co., Ltd. [trade names: Oscar 1132 (particle diameter of 12 nm; dispersing agent is methanol), OSCAR 1332 (particle diameter of 12 nm; dispersant n-propanol), OSCAR 105 (particle size 60 nm; dispersant γ-butyrolactone), OSCAR 106 (particle diameter of 120 nm; dispersant diacetone alcohol), etc.]; commercially available products by Fuso Chemical Co. [trade names: Quartron PL-1-IPA (particle diameter of 13 nm; dispersant isobutyl ketone), Quartron PL-1-TOL (particle diameter of 13 nm; dispersant toluene), Quartron PL-2L-PGME (18 nm particle size; diacetone alcohol propylene glycol monomethyl ether) or Quartron PL-2L-MEK (particle size 18 nm; dispersant methyl ethyl ketone)]; or commercially available products manufactured by Nissan Chemical Company [trade names, such as IPA-ST (particle diameter 12 nm; dispersant isopropanol), EG-ST (particle diameter of 12 nm; dispersant ethylene glycol), IPA-ST-L (particle size 45 nm; dispersant isopropanol) or IPA-ST-ZL (particle diameter of 100 nm; dispersant isopropyl alcohol)].

A general method can be applied in the condensation reaction, for example, adding solvents, water and optionally catalyst in the mixture, and heating and stirring under 50° C. to 150° C. for 0.5 to 120 hours, and removing byproducts (alcohols, water, etc.) by distillation with stirring.

The solvent used in the aforementioned reaction is not particularly limited, and the solvent can be the same or different from the solvent (D) included in the photosensitive polysiloxane composition according to the present invention. Based on 100 parts by weight of the total used amount of the silane monomers, the used amount of the solvent is from 15 g to 1200 g; preferably 20 g to 1100 g; and more preferably 30 g to 1000 g.

Based on 1 mole of hydrolyzable groups contained in the mixture, the used amount of the water in the aforementioned reaction is from 0.5 moles to 2 moles.

The catalyst is not particularly limited, and is preferably selected from the group consisting of an acidic catalyst and a basic catalyst. The acidic catalyst includes but is not limited to hydrochloric acid, nitric acid, sulfuric acid, hydrofluoric acid, oxalic acid, phosphoric acid, acetic acid, trifluoroacetic acid, formic acid, polybasic carboxylic acid or an anhydride thereof, or ion exchange resins. The basic catalyst includes but is not limited to diethylamine, triethylamine, tripropylamine, tributylamine, tripentylamine, trihexylamine, triheptylamine, trioctylamine, diethanolamine, triethanolamine, sodium hydroxide, and potassium hydroxide, the amine group-containing silane having an alkoxy group or ion exchange resins and the like.

Based on 100 parts by weight of the total used amount of the silane monomers, the used amount of the catalyst in the aforementioned reaction preferably is from 0.005 to 15 g; more preferably 0.01 to 12; and most preferably 0.05 to 10 g.

Concerning stability, the polysiloxane (A) manufactured by the condensation reaction preferably excludes the byproducts (such as alcohols or water) and the catalyst. Therefore the polysiloxane (A) can be optionally purified. The purification method is not particularly limited. Preferably, a hydrophobic solvent is used for the dilution of the polysiloxane (A). Subsequently, the organic layer is washed with water several times and concentrated by a rotary evaporator to remove the alcohols or water. In addition, ion exchange resins can be used to remove the catalyst.

The kind of the o-naphthoquinone diazide sulfonic acid ester (B) according to the present invention is not particularly limited, and common o-naphthoquinone diazide sulfonic acid esters can be used. The o-naphthoquinone diazide sulfonic acid ester (B) can be completely esterified or partially esterified ester-based compound.

The O-naphthoquinone diazide sulfonic acid ester (B) is preferably prepared by reacting an o-naphthoquinone diazide sulfonic acid or salts thereof with a hydroxy compound. The O-naphthoquinone diazide sulfonic acid ester (B) is more preferably prepared by reacting the o-naphthoquinone diazide sulfonic acid or salts thereof with a polyhydroxy compound.

The O-naphthoquinone diazide sulfonic acid is, for example, o-naphthoquinone diazide-4-sulfonic acid, o-naphthoquinone diazide-5-sulfonic acid or o-naphthoquinone diazide-6-sulfonic acid. In addition, the o-naphthoquinone diazide sulfonic acid salts are, for example, o-naphthoquinone diazonaphthoquinone sulfonyl halides.

The hydroxy compound is, for example:
(1) Hydroxybenzophenone-based compounds, such as, 2,3,4-trihydroxy-benzophenone, 2,4,4′-trihydroxy-benzophenone, 2,4,6-trihydroxy-benzophenone, 2,3,4,4′-tetrahydroxy benzophenone, 2,4,2′,4′-tetrahydroxy benzophenone, 2,4,6,3′,4′-pentahydroxy-benzophenone, 2,3,4,2′,4′-pentahydroxy-benzophenone, 2,3,4,2′,5′-pentahydroxy-benzophenone, 2,4,5,3′,5′-pentahydroxy-benzophenone or 2,3,4,3′,4′,5′-hexahydroxy-benzophenone.
(2) Hydroxyaryl-based compounds, for example, a hydroxy aryl compound represented by Formula (I):

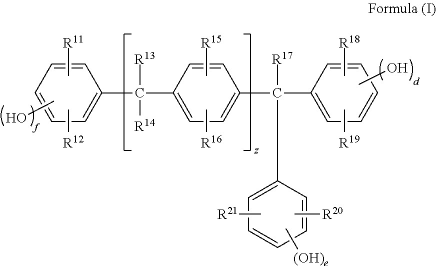

in Formula (I), wherein, each R¹¹ and R¹² independently represents a hydrogen atom, a halogen atom or a C₁-C₆ alkyl group; each R¹³, R¹⁴, R¹⁷ independently represents a hydrogen atom or a C₁-C₆ alkyl group; each R¹⁵, R¹⁶, R¹⁸, R¹⁹, R²⁰ and R²¹ independently represents a hydrogen atom, a halogen atom, a C₁-C₆ alkyl group, a C₁-C₆ alkoxy group, a C₁-C₆ alkenyl group or a C₁-C₆ cycloalkyl group; each d, e and f independently represents an integer selected from 1 to 3; z represents 0 or 1.

The hydroxyaryl-based compounds represented in Formula (I) are, for example, tris(4-hydroxyphenyl) methane, bis(4-hydroxy-3,5-dimethyl-phenyl)-4-hydroxyphenyl methane, bis(4-hydroxy-3,5-dimethyl-phenyl)-3-hydroxyphenyl methane, bis(4-hydroxy-3,5-dimethyl-phenyl)-2-hydroxyphenyl methane, bis(4-hydroxy-2,5-dimethylphenyl)-4-hydroxyphenyl methane, bis(4-hydroxy-2,5-dimethylphenyl)-3-hydroxyphenyl methane, bis(4-hydroxy-2,5-dimethylphenyl)-2-hydroxyphenyl methane, bis(4-hydroxy-3,5-dimethylphenyl)-3,4-bis(hydroxyphenyl) methane, bis(4-hydroxy-2,5-dimethylphenyl)-3,4-dihydroxyphenyl methane, bis(4-hydroxy-3,5-dimethylphenyl)-2,4-hydroxyphenyl methane, bis(4-hydroxy-2,5-dimethylphenyl)-2,4-dihydroxyphenyl methane, bis(4-hydroxyphenyl)-3-methoxy-4-hydroxyphenyl methane, bis(3-cyclohexyl-4-hydroxyphenyl)-3-hydroxyphenyl methane, bis(3-cyclohexyl-4-hydroxyphenyl)-2-hydroxyphenyl methane, bis(3-cyclohexyl-4-hydroxyphenyl)-4-hydroxyphenyl methane, bis(3-cyclohexyl-4-hydroxy-6-methyl-phenyl)-2-hydroxyphenyl methane, bis(3-cyclohexyl-4-hydroxy-6-methyl-phenyl)-3-hydroxyphenyl methane, bis(3-cyclohexyl-4-hydroxy-6-methylphenyl)-4-hydroxyphenyl methane, bis(3-cyclohexyl-4-hydroxy-6-methyl-phenyl)-3,4-dihydroxyphenyl methane, bis(3-cyclohexyl-6-hydroxyphenyl)-3-hydroxyphenyl methane, bis(3-cyclohexyl-6-hydroxyphenyl)-4-hydroxyphenyl methane, bis(3-cyclohexyl-6-hydroxyphenyl)-2-hydroxyphenyl methane, bis(3-cyclohexyl-6-hydroxy-4-methylphenyl)-2-hydroxyphenyl methane, bis(3-cyclohexyl-6-hydroxy-4-methylphenyl)-4-hydroxyphenyl methane, bis(3-cyclohexyl-6-hydroxy-4-methyl-phenyl)-3,4-dihydroxyphenyl methane, 1-[1-(4-hydroxyphenyl)isopropyl]-4-[1,1-bis(4-hydroxyphenyl)ethyl]benzene or 1-[1-(3-methyl-4-hydroxyphenyl)isopropyl]-4-[1,1-bis(3-methyl-4-hydroxyphenyl)ethyl]benzene.
(3) (Hydroxyphenyl) hydrocarbon compounds, for example, (hydroxyphenyl) hydrocarbon compounds represented by Formula (II):

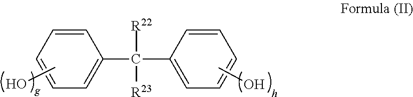

wherein in Formula (II), each R²² and R²³ independently represents a hydrogen atom or a C₁-C₆ alkyl group; each g and h independently represents an integer selected from 1 to 3.

The (hydroxyphenyl)-hydrocarbon compounds represented in Formula (II) are, such as, 2-(2,3,4-trihydroxyphenyl)-2-(2′,3′,4′-trihydroxyphenyl) propane, 2-(2,4-dihydroxyphenyl)-2-(2′,4′-dihydroxyphenyl) propane, 2-(4-hydroxyphenyl)-2-(4′-hydroxyphenyl) propane, bis(2,3,4-trihydroxyphenyl) methane, bis(2,4-dihydroxyphenyl) methane or the like.
(4) Other aromatic hydroxyl compounds are, such as phenol, p-methoxyphenol, dimethylphenol, hydroquinone, bisphenol A, naphthol, catechol, 1,2,3-pyrogallol methyl ether, 1,2,3-pyrogallol-1,3-dimethyl ether, 3,4,5-trihydroxy benzoic acid, or partially esterified or etherified 3,4,5-trihydroxy benzoic acid.

The hydroxy compound is preferably 1-[1-(4-hydroxyphenyl) isopropyl]-4-[1,1-bis(4-hydroxyphenyl)ethyl]benzene, 2,3,4-trihydroxy-benzophenone, 2,3,4,4′-tetrahydroxy benzophenone, or a combination thereof. The hydroxy compounds can be used singly or in combination.

The reaction of the o-naphthoquinone diazide sulfonic acid or salts thereof with the hydroxy compound is usually performed in an organic solvent, such as dioxane, N-pyrrolidone, acetamides and etc. Furthermore, the reaction is preferably performed in an alkaline condensing agent, such as triethanolamine, alkali metal carbonates or alkali metal bicarbonates.

The degree of esterification of the o-naphthoquinone diazide sulfonic acid ester (B) is preferably more than 50%. That is, based on 100 mol % of the used amount of the hydroxyl groups in the hydroxy compound, 50 mole % or more hydroxyl groups in the hydroxy compound react with the o-naphthoquinone diazide sulfonic acid or salts thereof in the esterification reaction. The degree of esterification of the o-naphthoquinone diazide sulfonic acid ester (B) is more preferably 60% or more.

Based on 100 parts by weight of the used amount of the polysiloxane (A), the used amount of the o-naphthoquinone diazide sulfonic acid ester (B) is from 1 part by weight to 30 parts by weight; preferably 3 parts by weight to 25 parts by weight; and more preferably 5 parts by weight to 25 parts by weight.

The thermal base generator (C) according to the present invention comprises a compound represented by Formula (4) or an salt derivative thereof and/or a compound represented by Formula (5) and/or a compound represented by Formula (6):

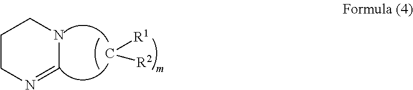

wherein:
m represents an integer of 2 to 6; and
R¹ and R² independently represent a hydrogen atom, a C₁-C₈ alkyl group, a substituted or unsubstituted C₁-C₆ hydroxyalkyl group, or a C₂-C₁₂ dialkylamino group.

In one embodiment of the invention, R¹ and R² independently represent a hydrogen atom; a C₁-C₈ alkyl group, for example: methyl, ethyl, isopropyl, n-butyl, tert-butyl or n-hexyl; a substituted or unsubstituted C₁-C₆ hydroxyalkyl group, for example: hydroxymethyl, 2-hydroxyethyl, 2-hydroxypropyl, 2-hydroxy isopropyl, 3-hydroxy-tert-butyl or 6-hydroxyhexyl; a C₂-C₁₂ dialkylamino group, for example: dimethylamino, methylethylamino, diethylamino, di-isopropylamino, tert-butyl-methylamino or di-n-hexylamino.

The preferred examples of the aforementioned compound represented by Formula (4) or the salt derivative thereof are 1,5-diazabicyclo[4.3.0]non-5-ene (DBN), 1,5-diazabicyclo[4.4.0]dec-5-ene, 1,8-diazabicyclo[5.4.0]undec-7-ene (DBU), 5-hydroxypropyl-1,8-diazabicyclo[5.4.0]undec-7-ene, 5-dibutylamino-1,8-diazabicyclo[5.4.0]undec-7-ene or the commercially available products manufactured by Aporo Co., Ltd.: U-CAT® SA810, U-CAT® SA831, U-CAT® SA841, U-CAT® SA851, U-CAT® 5002; more preferably, DBN, U-CAT® SA851 or U-CAT® 5002.

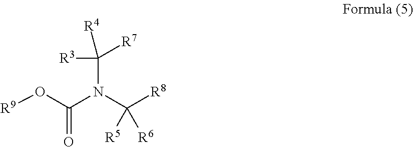

wherein:
R³, R⁴, R⁵ and R⁶ independently represent a hydrogen atom, a substituted or unsubstituted C₁-C₈ alkyl group, a substituted or unsubstituted C₃-C₈ cycloalkyl group, a substituted or unsubstituted C₁-C₈ alkoxy group, a substituted or unsubstituted C₂-C₈ alkenyl group, a substituted or unsubstituted C₂-C₈ alkynyl group, a substituted or unsubstituted aryl group, or a substituted or unsubstituted heterocyclic group;
R⁷ and R⁸ independently represent a hydrogen atom, a substituted or unsubstituted C₁-C₈ alkyl group, a substituted or unsubstituted C₃-C₈ cycloalkyl group, a substituted or unsubstituted C₁-C₈ alkoxy group, a substituted or unsubstituted C₂-C₈ alkenyl group, a substituted or unsubstituted C₂-C₈ alkynyl group, a substituted or unsubstituted aryl group, or a substituted or unsubstituted heterocyclic group, or R⁷ and R⁸ together form a substituted or unsubstituted monocyclic group, or R⁷ and R⁸ together form a substituted or unsubstituted polycyclic group;
R⁹ represents a substituted or unsubstituted C₁-C₁₂ alkyl group, a substituted or unsubstituted C₃-C₁₂ cycloalkyl group, a substituted or unsubstituted C₂-C₁₂ alkenyl group, a substituted or unsubstituted C₂-C₁₂ alkynyl group, an unsubstituted aryl group, an aryl group substituted with a C₁-C₃ alkyl group, an unsubstituted aralkyl, an aralkyl group substituted with a C₁-C₃ alkyl group or a substituted or unsubstituted heterocyclic group; the total carbon atom amount of R⁹ is below 12.

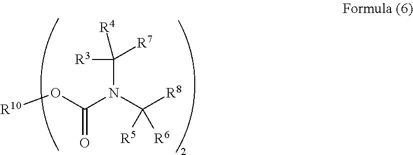

wherein:
R³, R⁴, R⁵, R⁶, R⁷ and R⁸ are as defined in Formula (5);
R¹⁰ represents a substituted or unsubstituted C₁-C₁₂ alkylene group, a substituted or unsubstituted C₃-C₁₂ cycloalkylene group, a substituted or unsubstituted C₂-C₁₂ alkenylene group, a substituted or unsubstituted C₂-C₁₂ alkynylene group, an unsubstituted arylene group, an arylene group substituted with a C₁-C₃ alkyl group, an unsubstituted aralkylene group, an aralkylene group substituted with a C₁-C₃ alkyl group or a substituted or unsubstituted heterocyclic group; the total carbon atom amount of R¹⁰ is below 12.

The preferred examples of the aforementioned compounds represented by Formula (5) and Formula (6) are N-(isopropoxycarbonyl)-2,6-dimethyl piperidine, N-(isopropoxycarbonyl)-2,2,6,6-tetramethyl piperidine, N-(isopropoxycarbonyl)diisopropylamine, N-(isopropoxycarbonyl) pyrrolidine, N-(isopropoxycarbonyl)-2,5-dimethyl pyrrolidine, N-(isopropoxycarbonyl) azetidine, N-(1-ethylpropoxycarbonyl)-2,6-dimethyl piperidine, N-(1-ethylpropoxycarbonyl)-2,2,6,6-tetramethyl piperidine, N-(1-ethylpropoxycarbonyl)diisopropylamine, N-(1-ethylpropoxycarbonyl) pyrrolidine, N-(1-ethylpropoxycarbonyl)-2,5-dimethyl pyrrolidine, N-(1-ethylpropoxycarbonyl) azetidine, N-(1-propylbutoxycarbonyl)-2,6-dimethyl piperidine, N-(1-propylbutoxycarbonyl)-2,2,6,6-tetramethyl piperidine, N-(1-propylbutoxycarbonyl)diisopropylamine, N-(1-propylbutoxycarbonyl) pyrrolidine, N-(1-propylbutoxycarbonyl)-2,5-dimethyl pyrrolidine, N-(1-propylbutoxycarbonyl) azetidine, N-(cyclopentyloxycarbonyl)-2,6-dimethyl piperidine, N-(cyclopentyloxycarbonyl)-2,2,6,6-tetramethyl piperidine, N-(cyclopentyloxycarbonyl)diisopropylamine, N-(cyclopentyloxycarbonyl) pyrrolidine, N-(cyclopentyloxycarbonyl)-2,5-dimethyl pyrrolidine, N-(cyclopentyloxycarbonyl) azetidine, N-(cyclohexylcarbonyl)-2,6-dimethyl piperidine, N-(cyclohexylcarbonyl)-2,2,6,6-tetramethyl piperidine, N-(cyclohexylcarbonyl)diisopropylamine, N-(cyclohexylcarbonyl) pyrrolidine, N-(cyclohexylcarbonyl)-2,5-dimethyl pyrrolidine, N-(cyclohexylcarbonyl) azetidine, N-(tert-butoxycarbonyl)-2,6-dimethyl piperidine, N-(tert-butoxycarbonyl)-2,2,6,6-tetramethyl piperidine, N-(tert-butoxycarbonyl)diisopropylamine, N-(tert-butoxycarbonyl) pyrrolidine, N-(tert-butoxycarbonyl)-2,5-dimethyl pyrrolidine, N-(tert-butoxycarbonyl) azetidine, N-(benzyloxycarbonyl)-2,6-dimethyl piperidine, N-(benzyloxycarbonyl)-2,2,6,6-tetramethyl piperidine, N-(benzyloxycarbonyl)diisopropylamine, N-(benzyloxycarbonyl) pyrrolidine, N-(benzyloxycarbonyl)-2,5-dimethyl pyrrolidine, N-(benzyloxycarbonyl) azetidin or 1,4-bis(N,N′-diisopropylaminocarbonyl)cyclohexane; preferably N-(isopropoxycarbonyl)-2,6-dimethyl piperidine, N-(1-ethylpropoxycarbonyl)diisopropylamine, N-(cyclopentyloxycarbonyl)-2,6-dimethyl piperidine, N-(benzyloxycarbonyl) pyrrolidine or 1,4-bis(N,N′-diisopropylaminecarbonyl)cyclohexane.

Based on 100 parts by weight of the used amount of the polysiloxane (A), the used amount of the thermal base generator (C) is from 0.05 parts by weight to 40 parts by weight; preferably 1 parts by weight to 40 parts by weight; and more preferably 1 parts by weight to 35 parts by weight.

If the thermal base generator (C) is absent, the photosensitive polysiloxane composition is not cured well at low temperature. Though not willing to be limited by theory, it is believed that the thermal base generator (C) has fast reaction rate under an alkaline environment which can improve the curing at low temperature.

The kind of the solvent (D) according to the present invention is not particularly limited. The solvent (D) is, for example, a compound containing an alcoholic hydroxy group or a cyclic compound containing a carbonyl group.

The compound containing the alcoholic hydroxy group is, for example, acetol, 3-hydroxy-3-methyl-2-butanone, 4-hydroxy-3-methyl-2-butanone, 5-hydroxy-2-pentanone, 4-hydroxy-4-methyl-2-pentanone (also called as diacetone alcohol, DAA), ethyl lactate, butyl lactate, propylene glycol monomethyl ether, propylene glycol monoethyl ether (PGEE), propylene glycol monomethyl ether acetate (PGMEA), propylene glycol mono-n-propyl ether, propylene glycol mono-n-butyl ether, propylene glycol mono-t-butyl ether, 3-methoxy-1-butanol, 3-methyl-3-methoxy-1-butanol or a combination thereof. It is noted that the compound containing the alcoholic hydroxy group is preferably diacetone alcohol, ethyl lactate, propylene glycol monoethyl ether, propylene glycol methyl ether acetate or combinations thereof. The compound containing the alcoholic hydroxy group can be used singly or in combination.

The cyclic compound containing the carbonyl group is, for example, γ-butyrolactone, γ-valerolactone, δ-valerolactone, propylene carbonate, N-methyl pyrrolidone, cyclohexanone or cycloheptanone. It is noted that the cyclic compound containing the carbonyl group is preferably γ-butyrolactone, N-methyl pyrrolidone, cyclohexanone or combinations thereof. The cyclic compound containing the carbonyl group may be used singly or in combination.

The compound containing the alcoholic hydroxy group can be used in combination with the cyclic compound containing the carbonyl group, and the mixing weight ratio of both is not particularly limited. The weight ratio of the compound containing the alcoholic hydroxy group and the cyclic compound containing the carbonyl group ranges preferably from 99/1 to 50/50; more preferably from 95/5 to 60/40. It is noted that when the weight ratio of the compound containing the alcoholic hydroxy group and the cyclic compound containing the carbonyl group is from 99/1 to 50/50 in the solvent (D), the unreacted silanol (Si—OH) groups in the polysiloxane (A) are unlikely to carry on a condensation reaction and the storage stability is lowered. In addition, since the compound containing the alcoholic hydroxy group and the cyclic compound containing the carbonyl group have good compatibility with the o-naphthoquinone diazide sulfonic acid ester (B), a whitening phenomenon hardly occurs in the coating film and the transparency of the thin film can be maintained.

Without lowering the effect of the present invention, other solvents can be included. These other solvents can be, for example: (1) esters: ethyl acetate, n-propyl acetate, iso-propyl acetate, n-butyl acetate, isobutyl acetate, propylene glycol monomethyl ether acetate, 3-methoxy-1-butyl acetate or 3-methyl-3-methoxy-1-butyl acetate, etc.; (2) ketones: methyl isobutyl ketone, diisopropyl ketone, or di-isobutyl ketone, etc.; or (3) ethers: diethyl ether, diisopropyl ether, di-n-butyl ether or diphenyl ether etc.

Based on 100 parts by weight of the used amount of the polysiloxane (A), the used amount of the solvent (D) is from 100 parts by weight to 1000 parts by weight; preferably 150 parts by weight to 900 parts by weight; and more preferably 200 parts by weight to 800 parts by weight.

The photosensitive polysiloxane composition of the present invention can optionally further include an additive (E). The additive (E) can be, for example, a sensitizer, adhesion auxiliary agent, surfactant, solubility promoter, defoamer, or combinations thereof.

The kind of the sensitizer is not particularly limited. The sensitizer can use preferably a compound containing a phenolic hydroxyl group, for example:
(1) a trisphenol type compound: such as tris(4-hydroxyphenyl) methane, bis(4-hydroxy-3-methylphenyl)-2-hydroxyphenyl methane, bis(4-hydroxy-2,3,5-trimethylphenyl)-2-hydroxyphenyl methane, bis(4-hydroxy-3,5-dimethylphenyl)-4-hydroxyphenyl methane, bis(4-hydroxy-3,5-dimethylphenyl)-3-hydroxyphenyl methane, bis(4-hydroxy-3,5-methylphenyl)-2-hydroxyphenyl methane, bis(4-hydroxy-2,5-dimethylphenyl)-4-hydroxyphenyl methane, bis(4-hydroxy-2,5-dimethylphenyl)-3-hydroxyphenyl methane, bis(4-hydroxy-2,5-dimethylphenyl)-2-hydroxyphenyl methane, bis(4-hydroxy-3,5-dimethylphenyl)-3,4-dihydroxyphenyl methane, bis(4-hydroxy-2,5-dimethylphenyl)-3,4-dihydroxyphenyl methane, bis(4-hydroxy-2,5-dimethylphenyl)-2,4-bis(hydroxyphenyl) methane, bis(4-hydroxyphenyl)-3-methoxy-4-hydroxyphenyl methane, bis(5-cyclohexyl-4-hydroxy-2-methylphenyl)-4-hydroxyphenyl methane, bis(5-cyclohexyl-4-hydroxy-2-methylphenyl)-3-hydroxyphenyl methane, bis(5-cyclohexyl-4-hydroxy-2-methylphenyl)-2-hydroxyphenyl methane or bis(5-cyclohexyl-4-hydroxy-2-methylphenyl)-3,4-dihydroxyphenyl methane, etc.;
(2) a bisphenol type compound: such as bis(2,3,4-trihydroxyphenyl) methane, bis(2,4-dihydroxyphenyl) methane, 2,3,4-trihydroxyphenyl-4′-hydroxyphenyl methane, 2-(2,3,4-trihydroxyphenyl)-2-(2′,3′,4′-trihydroxyphenyl) propane, 2-(2,4-dihydroxyphenyl)-2-(2′,4′-dihydroxyphenyl) propane, 2-(4-hydroxyphenyl)-2-(4′-hydroxyphenyl) propane, 2-(3-fluoro-4-hydroxyphenyl)-2-(3′-fluoro-4′-hydroxyphenyl) propane, 2-(2,4-dihydroxyphenyl)-2-(4′-hydroxyphenyl) propane, 2-(2,3,4-trihydroxyphenyl)-2-(4′-hydroxyphenyl) propane or 2-(2,3,4-trihydroxyphenyl)-2-(4′-hydroxy-3′,5′-dimethylphenyl) propane and the like;
(3) a polynuclear branched compounds: such as 1-[1-(4-hydroxyphenyl)isopropyl]-4-[1,1-bis(4-hydroxyphenyl)ethyl]phenyl or 1-[1-(3-methyl-4-hydroxyphenyl)isopropyl]-4-[1,1-bis(3-methyl-4-hydroxyphenyl)ethyl]benzene and the like;
(4) a condensation type phenol compound: such as 1,1-bis(4-hydroxyphenyl)cyclohexane, etc.;
(5) a polyhydroxy benzophenones: such as 2,3,4-trihydroxy benzophenone, 2,4,4′-trihydroxy benzophenone, 2,4,6-trihydroxy benzophenone, 2,3,4-trihydroxy-2′-methylbenzophenone, 2,3,4,4′-tetrahydroxy benzophenone, 2,4,2′,4′-tetrahydroxy benzophenone, 2,4,6,3′,4′-pentahydroxy benzophenone, 2,3,4,2′,4′-pentahydroxy benzophenone, 2,3,4,2′,5′-pentahydroxy benzophenone, 2,4,6,3′,4′,5′-hexahydroxy benzophenone or 2,3,4,3′,4′,5′-hexahydroxy benzophenone; or
(6) combinations of the aforementioned compounds containing the phenolic hydroxyl group.

Based on 100 parts by weight of the used amount of the polysiloxane (A), the used amount of the sensitizer is from 5 parts by weight to 50 parts by weight; preferably 8 parts by weight to 40 parts by weight; and more preferably 10 parts by weight to 35 parts by weight.

The adhesion auxiliary agent is, for example, a melamine compound, and a silane-based compound. The role of the adhesion auxiliary agent is to increase the adhesion between the device or component and the thin film that is formed by the photosensitive polysiloxane composition.

Commercially available products of melamine compounds are, for example, manufactured by Mitsui Chemicals, trade names Cymel 300, Cymel-303, etc.; or the products manufactured by Sanwa Chemical, trade names MW-30MH, MW-30, MS-11, MS-001, MX-750 or MX-706.

When using the melamine compound as the adhesion auxiliary agent, based on 100 parts by weight of the used amount of the polysiloxane (A), the used amount of the melamine compound is from 0 part by weight to 20 parts by weight; preferably 0.5 parts by weight to 18 parts by weight; and more preferably 1.0 part by weight to 15 parts by weight.

The silane-based compound is, for example, vinyltrimethoxysilane, vinyltriethoxysilane, 3-acryloxypropyltrimethoxysilane, vinyl tris(2-methoxyethoxy)silane, N-(2-aminoethyl)-3-aminopropylmethyldimethoxysilane, N-(2-aminoethyl)-3-aminopropyltrimethoxysilane, 3-aminopropyltriethoxysilane, 3-glycidoxypropyltrimethoxysilane, 3-glycidoxypropyldimethylmethoxysilane, 2-(3,4-epoxycyclohexyl)ethyltrimethoxysilane, 3-chloropropylmethyldimethoxysilane, 3-chloropropyltrimethoxysilane, 3-methacryloxypropyltrimethoxysilane, 3-mercaptopropyltrimethoxysilane or a commercially available product manufactured by Shin-Etsu Chemical Company (trade name of KBM403).

When using the silane-based compound as the adhesion auxiliary agent, based on 100 parts by weight of the used amount of the polysiloxane (A), the used amount of the silane-based compound is from 0 part by weight to 2 parts by weight; preferably 0.05 parts by weight to 1 part by weight; and more preferably 0.1 parts by weight to 0.8 parts by weight.

The surfactants are, for example, anionic surfactants, cationic surfactants, nonionic surfactants, amphoteric surfactants, polysiloxane-based surfactants, fluorine-based surfactants or a combination thereof

Examples of the surfactant include (1) polyoxyethylene alkyl ethers: polyoxyethylene lauryl ether, etc.; (2) polyoxyethylene phenyl ethers: polyoxyethylene octyl phenyl ether, polyoxyethylene nonyl phenyl ether, etc.; (3) polyethylene glycol diesters: polyethylene glycol dilaurate, polyethylene glycol distearate, etc.; (4) sorbitan fatty acid esters; and (5) fatty acid modified poly esters; and (6) tertiary amine modified polyurethanes. Commercially available products of surfactant are, for example, KP (manufactured by Shin-Etsu Chemical), SF-8427 (manufactured by Dow Corning Toray Silicone Co., Ltd.), Polyflow (manufactured by Kyoeisha Grease Chemical), F-Top (manufactured by Tochem Products Co., Ltd.), Megaface (manufactured by Dainippon ink chemical industry (DIC)), Fluorade (by Sumitomo 3M Co., Ltd.), Surflon (manufactured by Asahi Glass), SINOPOL E8008 (Sino Japan Chemical Co. Ltd.), F-475 (manufactured by Dainippon ink chemical industry) or combinations thereof.

Based on 100 parts by weight of the used amount of the polysiloxane (A), the used amount of the surfactant is from 0.5 parts by weight to 50 parts by weight; preferably 1 part by weight to 40 parts by weight; and more preferably 3 parts by weight parts by weight to 30 parts by weight.

Examples of the defoamer include Surfynol MD-20, Surfynol MD-30, EnviroGem AD01, EnviroGem AE01, EnviroGem AE02, Surfynol DF110D, Surfynol 104E, Surfynol 420, Surfynol DF37, Surfynol DF58, Surfynol DF66, Surfynol DF70 and Surfynol DF210 (manufactured by Air products) and the like. Based on 100 parts by weight of the used amount of the polysiloxane (A), the used amount of the defoamer is from 1 part by weight to 10 parts by weight; preferably 2 parts by weight to 9 parts by weight; and more preferably 3 parts by weight to 8 parts by weight.

Examples of the solubility promoter include N-hydroxydicarboxylic imide and a compound containing a phenolic hydroxyl group. For example, the solubility promoter is the compound containing the phenolic hydroxyl group used in the o-naphthoquinone diazide sulfonic acid ester (B). Based on 100 parts by weight of the used amount of the polysiloxane (A), the used amount of the solubility promoter is from 1 to 20 parts by weight; preferably 2 to 15 parts by weight; and more preferably 3 to 10 parts by weight.

The photosensitive polysiloxane composition can be prepared in the following manner: placing the polysiloxane (A), the o-naphthoquinone diazide sulfonic acid ester (B), the thermal base generator (C) and the solvent (D) in a blender and stirring them until homogeneously mixed into a solution state. If necessary, the additive (E) can be added.

The present invention also provides a method for forming a thin film on a substrate comprising applying the photosensitive polysiloxane composition as mentioned above on the substrate.

The present invention also provides a thin film on a substrate, which is manufactured by the method as mentioned above.

The present invention further provides a device comprising the thin film. Preferably, the thin film is a planarization film of a TFT substrate in a liquid crystal display element or organic light-emitting display device, an interlayer insulating film or an overcoat of a core material or a protective material in a waveguide.

The following descriptions detail the method of forming the thin film, comprising: using a photosensitive polysiloxane composition to form a pre-baked coating film, pattern-exposing of the pre-baked coating film, removing the unexposed region of the film by an alkali developer to form a pattern, and performing a post-baking treatment to form the thin film.

### <Forming a Pre-Baked Coating Film>

By spin coating, cast coating, or roll coater coating method, the photosensitive polysiloxane composition in the above solution state is coated onto a device to be protected (hereinafter referred to as substrate), to form a coating film.

The above-mentioned substrate can be alkali-free glass, soda lime glass, Pyrex glass, quartz glass, or glasses adhered with a transparent conductive film used in a liquid crystal display device, or a substrate (such as, silicon substrate) used in the photoelectric conversion device (such as a solid-state imaging device).

After forming the coating film, most of the organic solvent of the photosensitive polysiloxane composition is removed by reducing pressure and drying method, and then all the residual organic solvent is removed completely by pre-baking method, to form a pre-baked coating film.

The above-mentioned operation condition can be different according to the kinds of the components and ratio. Generally, reducing pressure and drying are at a pressure of 0 Torr to 200 Torr for 1 second to 60 seconds, and pre-baking is at a temperature between 70° C. to 110° C. for 1 minute to 15 minutes.

### <Pattern-Exposing>

A mask having a specific pattern is used to perform exposure for the above-mentioned pre-baked coating film. The light used in the exposure process, is preferably ultraviolet (UV) rays (g line, h line, i line, etc.), and the device used to provide UV rays can be an ultra high-pressure mercury lamp or a metal halide lamp.

### <Developing>

Unnecessary portions of the above exposed pre-baked coating film are removed by immersing the pre-baked coating film in the developer solution at a temperature between 23±2° C. and developing for about 15 seconds to 5 minutes, so as to form a semi-finished product of the thin film with a predetermined pattern on the substrate. The developer can be alkaline compounds, such as, sodium hydroxide, potassium hydroxide, sodium carbonate, sodium hydrogen carbonate, potassium carbonate, potassium bicarbonate, sodium silicate, sodium methylsilicate, aqueous ammonia, ethylamine, diethylamine, dimethyl ethanolamine, tetramethylammonium hydroxide (THAM), tetraethylammonium hydroxide, choline, pyrrole, piperidine, or 1,8-diazabicyclo-(5,4,0)-7-undecene.

It is noted that if the concentration of the developer is too high, the specific pattern may be damaged or the resolution of the specific pattern may be deteriorated. If the concentration of the developer is too low, poor development may happen, and the specific pattern may not be formed or residues of the composition remain in the exposed portions. Therefore, the concentration of the developer affects the formation of the subsequent specific pattern of the photosensitive polysiloxane composition after exposure. The concentration range of the liquid developer is preferably from 0.001 wt % to 10 wt %; more preferably from 0.005 wt % to 5 wt %; further more preferably from 0.01 wt % to 1 wt %. The present embodiment of the present invention employs a developer of 2.38 wt % tetramethylammonium hydroxide. It is noted that even using a lower concentration of the developer, the photosensitive polysiloxane composition of the present invention is capable of forming a fine pattern.

### <Post-Baking>

The substrate (semi-finished product of the thin film with the predetermined pattern on the substrate) is washed with water to remove the unwanted portions of the above-mentioned exposed pre-baked coating film. Then, compressed air or compressed nitrogen is used to dry up the semi-finished product of the thin film with the predetermined pattern. Finally, the semi-finished product of the thin film with the predetermined pattern is post-baked on a heating plate or in an oven. The heating temperature is set between 100° C. to 250° C., and the heating time with the heating plate is 1 to 60 minutes or the heating time with the oven is 5 to 90 minutes. Thereby, the semi-finished product of the thin film with the predetermined pattern is cured to form a thin film.

The present invention will provide more details hereinafter in the following embodiments, but it should be understood that these examples are only illustrative and for illustrative purposes and should not be construed to limit the present invention.

### Synthesis of Polysiloxane

### Synthesis Example A-1

Adding 0.05 mole of 3-(triethoxysilyl) propyl succinic anhydride (hereinafter referred to as GF-20), 0.05 mole of 3-glycidoxypropyltriethoxysilane (hereinafter referred to as GMATES, 0.30 mole of methyltrimethoxysilane (hereinafter referred to as MTMS), 0.60 mole of phenyltrimethoxysilane (hereinafter referred to as PTMS) and 200 g of propylene glycol monoethyl ether (hereinafter referred to PGEE) into a 500 ml three-necked flask, an aqueous oxalic acid solution (0.40 g oxalic acid/75 g water) was added at room temperature with stirring within 30 minutes. Next, the flask was immersed at 30° C. in oil bath and stirred for 30 minutes. Then, within 30 minutes, the temperature of the oil bath was raised to 120° C. After the solution temperature was dropped to 105° C., heating was resumed with stirring for polymerization for 6 hours. Then again, the solvent was removed using distillation to obtain the polysiloxane A-1. The kinds and used amounts of the raw materials of the polysiloxane A-1 are shown in Table 1.

### Synthesis Examples A-2 to A-17

Synthesis examples A-2 to A-17 were practiced with the analogous method as in Synthesis example A-1 by using various kinds or amounts of the components of the silane monomer and polysiloxane which were listed in Table 1. The amounts of solvent and oxalic acid, the reaction temperature and the time of polymerization and condensation were different from those of the aforementioned polysiloxane (A-1) which were also listed in Table 1.

TABLE 1

| | Composition | | | |
|---|---|---|---|---|
| | silane monomer (mol) | | | |
| | | | silane monomer | |
| | | | (a-3) | |
| | silane monome | silane monomer | silane monomer | silane monomer |
| Prepa- | r(a-1) | (a-2) | (a-3-1) | (a-3-2) |

| ration | GF-20 | DESDS | TMSG | GMATES | TMSOX-D | ECETES | TESOX-D | TEOS | TPOS | TMOS | MTMS | DMDMS |
|---|---|---|---|---|---|---|---|---|---|---|---|---|
| A-1 | 0.05 | | | 0.05 | | | | | | | 0.30 | |
| A-2 | | 0.10 | | | | 0.10 | 0.10 | | | | | 0.40 |
| A-3 | | | 0.15 | | 0.20 | 0.20 | | | | | | 0.20 |
| A-4 | | 0.20 | | | 0.30 | | | | | | 0.29 | |
| A-5 | 0.01 | | | | | 0.01 | | | | | 0.40 | |
| A-6 | 0.03 | | | 0.07 | | | | 0.50 | | | 0.10 | |
| A-7 | | 0.05 | | | | 0.10 | | | 0.10 | | 0.20 | |
| A-8 | | | 0.10 | 0.05 | | | | 0.30 | | 0.30 | | |
| A-9 | 0.08 | | | | 0.12 | | | | | 0.40 | 0.40 | |
| A-10 | | 0.03 | | | | 0.02 | | | 0.10 | 0.10 | | 0.30 |
| A-11 | 0.005 | | | 0.02 | 0.03 | | | 0.10 | | | 0.30 | |
| A-12 | | 0.25 | | | | 0.20 | | 0.10 | 0.10 | | | |
| A-13 | 0.10 | | | | 0.005 | | | | | 0.30 | 0.20 | |
| A-14 | | 0.05 | | | | 0.45 | | | 0.30 | | | |
| A-15 | | 0.05 | | | | | | | | | 0.45 | |
| A-16 | | | | | 0.30 | | | | | | | 0.50 |
| A-17 | | | | | | | | | | | | 0.50 |

| | Composition | | | | | | | | |
|---|---|---|---|---|---|---|---|---|---|
| | silane monomer (mol) | | | | | | | | |
| | silane monomer (a-3) | | other | | | Catalyst (g) | | | |
| | silane monomer (a-3-2) | | polysiloxane | Solvent (g) | | DI | Oxalic | Temp. | Time |
| | PTMS | PTES | DMS-S27 | PGEE | DAA | water | acid | (° C.) | (hour) |
| A-1 | 0.60 | | | 200 | | 75 | 0.40 | 105 | 6 |
| A-2 | | 0.30 | | 100 | 100 | 75 | 0.40 | 110 | 5 |
| A-3 | 0.25 | | | 200 | | 75 | 0.35 | 105 | 6 |
| A-4 | | 0.20 | 0.01 | 200 | | 75 | 0.45 | 110 | 6 |
| A-5 | 0.58 | | | 200 | | 75 | 0.40 | 110 | 5 |
| A-6 | 0.30 | | | | 200 | 75 | 0.40 | 105 | 6 |
| A-7 | | 0.55 | | | 200 | 75 | 0.40 | 105 | 6 |
| A-8 | 0.25 | | | 200 | | 75 | 0.40 | 110 | 5 |
| A-9 | | | | 200 | | 75 | 0.40 | 105 | 6 |
| A-10 | 0.45 | | | 200 | | 75 | 0.40 | 110 | 6 |
| A-11 | | 0.545 | | 200 | | 75 | 0.40 | 105 | 5 |
| A-12 | 0.35 | | | 200 | | 75 | 0.35 | 110 | 5 |
| A-13 | 0.395 | | | | 200 | 75 | 0.40 | 110 | 6 |
| A-14 | 0.20 | | | 200 | | 75 | 0.40 | 110 | 5 |
| A-15 | | 0.50 | | 200 | | 75 | 0.40 | 110 | 5 |
| A-16 | | 0.20 | | 100 | 100 | 75 | 0.40 | 105 | 6 |
| A-17 | 0.30 | 0.20 | | 100 | 100 | 75 | 0.40 | 105 | 6 |

| | | Mw |
|---|---|---|
| GF-20 | 3-(triethoxysilyl) propyl succinic anhydride | 304 |
| DESDS | (dimethoxysilyl) di(ethyl succinic anhydride) | |
| TMSG | 3-(trimethoxysilyl) propyl glutaric anhydride | 276 |
| GMATES | 3-glycidoxypropyltriethoxysilane | |
| TMSOX-D | 2-oxetanylbutoxypropyltrimethoxysilane | 278 |
| ECETES | 2-(3,4-epoxycyclohexyl)ethyltrimethoxysilane | |
| TESOX-D | 2-oxetanylbutoxypropyltriethoxysilane | |
| TEOS | tetraethoxysilane | |
| TPOS | tetraphenoxy silane | |
| TMOS | tetramethoxysilane | |
| MTMS | methyltrimethoxysilane | 136 |
| DMDMS | dimethyldimethoxysilane | 120 |
| PTMS | phenyltrimethoxysilane | 198 |
| PTES | phenyltriethoxysilane | 240 |
| DMS-S27 | the silanol end portion of | 18000 |
| | polysiloxane(manufactured by Gelest Co., Ltd.) | |
| PGEE | propylene glycol monoethyl ether | 104 |
| DAA | diacetone alcohol | 116 |
| DI water | | 18 |
| Oxalic acid | | 90 |

### Examples and Comparative Examples

### Example 1

One-hundred parts by weight of the used amount of the polysiloxane (A-1), 1 part by weight of ortho-naphthoquinone diazide sulfonic acid ester formed from 1-[1-(4-hydroxyphenyl)isopropyl]-4-[1,1-bis(4-hydroxyphenyl)ethyl]benzene and ortho-naphthoquinone diazide-5-sulfonic acid (hereinafter referred to as B-1), and 0.05 parts by weight of 1,5-diazabicyclo[4.3.0]non-5-ene (DBN) (hereinafter referred to as C-1) were mixed and dissolved in 100 parts by weight of the propylene glycol monomethyl ether acetate (D-1) completely, so as to form the photosensitive polysiloxane composition of Example 1. A film obtained by the aforementioned Example 1 was subjected to assays shown below and the result was shown in Table 2.

### Examples 2 to 16 and Comparative Examples 1 to 5

The preparations of Examples 2 to 16 and Comparative Examples 1 to 5 were similar to that of Example 1 with modifications of the kinds and amounts of the compositions. The compositions and the results of the assays were shown in Table 2.

TABLE 2

| | | Example | | | | | | | | | | |
|---|---|---|---|---|---|---|---|---|---|---|---|---|
| Composition | | 1 | 2 | 3 | 4 | 5 | 6 | 7 | 8 | 9 | 10 | 11 |
| polysiloxane (A) | A-1 | 100 | | | | | | | | | | |
| (parts by weight) | A-2 | | 100 | | | | | | | | | |
| | A-3 | | | 100 | | | | | | | | |
| | A-4 | | | | 100 | | | | | | | |
| | A-5 | | | | | 100 | | | | | | |
| | A-6 | | | | | | 100 | | | | | |
| | A-7 | | | | | | | 100 | | | | |
| | A-8 | | | | | | | | 100 | | | |
| | A-9 | | | | | | | | | 100 | | |
| | A-10 | | | | | | | | | | 100 | |
| | A-11 | | | | | | | | | | | 100 |
| | A-12 | | | | | | | | | | | |
| | A-13 | | | | | | | | | | | |
| | A-14 | | | | | | | | | | | |
| | A-15 | | | | | | | | | | | |
| | A-16 | | | | | | | | | | | |
| | A-17 | | | | | | | | | | | |
| o-naphthoquinone diazide | B-1 | 1 | 5 | 10 | | 20 | 5 | 15 | 15 | 10 | 5 | 10 |
| sulfonic acid ester (B) | B-2 | | | | 15 | | 20 | | | | | |
| (parts by weight) | B-3 | | | | | | | 15 | | | 5 | |
| thermal base generator | C-1 | 0.05 | | | | | | | | | 3 | |
| (C) | C-2 | | 1.0 | | | | | | | 1 | | 5 |
| (parts by weight) | C-3 | | | 5 | | | | | | | 2 | |
| | C-4 | | | | 10 | | | | | | | |
| | C-5 | | | | | 20 | | | | | | 5 |
| | C-6 | | | | | | 30 | | | | | |
| | C-7 | | | | | | | 40 | | | | |
| | C-8 | | | | | | | | 20 | | | |
| solvent (D) | D-1 | 100 | 300 | 300 | 300 | | 300 | 500 | 600 | 800 | 300 | |
| (parts by weight) | D-2 | | | | 200 | 500 | | 300 | | | | 500 |
| | D-3 | | | | | | 300 | 200 | | | | |
| additive (E) | E-1 | | | | | | 1 | | | | | |
| (parts by weight) | E-2 | | | | 3 | | | | | | | |
| Evaluation | curing at low temperature | ◯ | ◯ | ◯ | ◯ | ◯ | ◯ | ⊚ | ⊚ | ⊚ | ⊚ | ◯ |

| | | Example | | | | | Comparative Example | | | | |
|---|---|---|---|---|---|---|---|---|---|---|---|
| Composition | | 12 | 13 | 14 | 15 | 16 | 1 | 2 | 3 | 4 | 5 |
| polysiloxane (A) | A-1 | | | | 50 | | | | | | |
| (parts by weight) | A-2 | | | | | 70 | 100 | | | | |
| | A-3 | | | | | | | | | | |
| | A-4 | | | | | | | | | | |
| | A-5 | | | | | | | | | | |
| | A-6 | | | | | | | | | | |
| | A-7 | | | | | | | | | | |
| | A-8 | | | | 50 | | | | | | |
| | A-9 | | | | | | | | | | |
| | A-10 | | | | | | | | | | |
| | A-11 | | | | | 30 | | | | | |
| | A-12 | 100 | | | | | | | | | |
| | A-13 | | 100 | | | | | | | | |
| | A-14 | | | 100 | | | | | | | |
| | A-15 | | | | | | | 100 | | | |
| | A-16 | | | | | | | | 100 | | |
| | A-17 | | | | | | | | | 100 | 100 |
| o-naphthoquinone diazide | B-1 | 20 | 10 | 10 | | 10 | 15 | | | 15 | 20 |
| sulfonic acid ester (B) | B-2 | | | 5 | | | | 15 | | | |
| (parts by weight) | B-3 | | | | 10 | | | | 15 | | |
| thermal base generator | C-1 | | | | | | | | | 10 | |
| (C) | C-2 | | 3 | | 3 | 5 | | 5 | | | |
| (parts by weight) | C-3 | | | | | | | | | | |
| | C-4 | 5 | | 5 | | | | | | | |
| | C-5 | | | | | | | | 10 | | |
| | C-6 | | | | | | | | | | |
| | C-7 | | | | | | | | | | |
| | C-8 | 10 | | | | 10 | | | | | |
| solvent (D) | D-1 | | 300 | 500 | 200 | 500 | 300 | | 500 | 500 | 500 |
| (parts by weight) | D-2 | | | | | | | 500 | | | |
| | D-3 | 300 | | | | | | | | | |
| additive (E) | E-1 | | | | | | | | | | |
| (parts by weight) | E-2 | | | | | | | | | | |
| Evaluation | curing at low temperature | ◯ | ◯ | ◯ | ⊚ | ◯ | X | X | X | X | X |

B-1 ortho-naphthoquinone diazide sulfonic acid ester formed from 1-[1-(4-hydroxyphenyl)isopropyl]-4-[1,1-bis(4-hydroxyphenyl)ethyl] benzene and ortho-naphthoquinone diazide-5-sulfonic acid
B-2 ortho-naphthoquinone diazide sulfonic acid ester formed from 2,3,4-trihydroxy-benzophenone and ortho-naphthoquinone diazide-5-sulfonic acid
B-3 ortho-naphthoquinone diazide sulfonic acid ester formed from 2,3,4,4′-tetrahydroxy benzophenone
C-1 1,5-diazabicyclo[4.3.0]non-5-ene (DBN)
C-2 U-CAT ® SA851
C-3 U-CAT ® 5002
C-4 N-(isopropoxycarbonyl)-2,6-dimethyl piperidine
C-5 N-(1-ethylpropoxycarbonyl) diisopropylamine
C-6 N-(cyclopentyloxycarbonyl)-2,6-dimethyl piperidine
C-7 N-(benzyloxycarbonyl) pyrrolidine
C-8 1,4-bis (N,N′-diisopropylaminecarbonyl) cyclohexane
D-1 propylene glycol monomethyl ether acetate
D-2 4-hydroxy-4-methyl-2-pentanone
D-3 cyclohexanone
E-1 SF-8427 (manufactured by Dow Corning Toray Silicone Co., Ltd., surfactant)
E-2 3-glycidoxypropyl trimethoxy silane (trade name of KBM403, manufactured by Shin-Etsu Chemical Company, adhesion auxiliary agent)

### <Evaluation Items>

### Curing at Low Temperature:

The photosensitive polysiloxane composition was spin coated independently on a prime glass substrate of 100×100×0.7 mm³ in size to obtain a pre-coated film of about 2 μm in thickness. After pre-baking the pre-coated film for 2 minutes at 110° C., a light mask with a given pattern was placed between the film and an exposure machine, and the film was exposed with ultraviolet light of 150 mJ/cm². Afterwards, the exposed film was immersed in 2.38% of tetramethylammonium hydroxide solution for 60 seconds to remove the exposed parts. After washing with pure water; and exposed film was radiated with the exposure machine directly at 200 mJ/cm². And then, the film was post-baked at different temperature for 60 minutes and a protective film on the glass was obtained. The protective film was evaluated by Pencil Scratch Hardness Tester (Mistubishi/P-247). A weight of 500 g was applied, and 1 cm of lines at six angles was drawn on the protective film by a 5H pencil at the rate of 0.5 mm/s. If more than two of the six lines (including 2 lines) have cracks, it means unqualified. The definition of the post-baking temperature was shown as following:

⊚: post-baking temperature≦140° C.;

◯: 140° C.<post-baking temperature≦200° C.;

x: 200° C.<post-baking temperature.

While embodiments of the present invention have been illustrated and described, various modifications and improvements can be made by persons skilled in the art. It is intended that the present invention is not limited to the particular forms as illustrated, and that all modifications not departing from the spirit and scope of the present invention are within the scope as defined in the following claims.

What is claimed is:

1. A photosensitive polysiloxane composition comprising:
a polysiloxane (A);
an o-naphthoquinone diazide sulfonic acid ester (B);
a thermal base generator (C); and
a solvent (D);
wherein
the polysiloxane (A) is a copolymer obtained by hydrolyzing and partial condensing a mixture comprising a silane monomer (a-1) represented by Formula (1), a silane monomer (a-2) represented by Formula (2) and a silane monomer (a-3) represented by Formula (3):
Si(Rₐ)_{w}(OR_{b})_{4-w} Formula (1),
wherein:
Rₐ represents a hydrogen atom, a C₁-C₁₀ alkyl group, a C₂-C₁₀ alkenyl group, a C₆-C₁₅ aryl group, an alkyl group having an acid anhydride group, an alkyl group having an epoxy group, or an alkoxy group having an epoxy group;
at least one of Rₐ represents the alkyl group having the acid anhydride group;
R_{b} represents a hydrogen atom, a C₁-C₆ alkyl group, a C₁-C₆ acyl group, or a C₆-C₁₅ aryl group; and
w represents an integer of 1 to 3; when w represents 2 to 3, each Rₐ is the same or different; when w represents 1 to 2, each R_{b} is the same or different;
Si(R_{c})ᵥ(OR_{d})₄₋ᵥ Formula(2),
wherein:
R_{c} represents a hydrogen atom, a C₁-C₁₀ alkyl group, a C₂-C₁₀ alkenyl group, a C₆-C₁₅ aryl group, an alkyl group having an acid anhydride group, an alkyl group having an epoxy group, or an alkoxy group having an epoxy group;
at least one of R_{c} represents the alkyl group having the epoxy group or the alkoxy group having the epoxy group;
R_{d} represents a hydrogen atom, a C₁-C₆ alkyl group, a C₁-C₆ acyl group, or a C₆-C₁₅ aryl group; and
v represents an integer of 1 to 3; when v represents 2 to 3, each R_{c} is the same or different; when v represents 1 to 2, each Rₑ is the same or different;
Si(Rₑ)ᵤ(OR_{f})₄₋ᵤ Formula (3),
wherein:
Rₑ represents a hydrogen atom, a C₁-C₁₀ alkyl group, a C₂-C₁₀ alkenyl group, a C₆-C₁₅ aryl group;
R_{f} represents a hydrogen atom, a C₁-C₆ alkyl group, a C₁-C₆ acyl group, or a C₆-C₁₅ aryl group; and
u represents an integer of 0 to 3; when u represents 2 to 3, each Rₑ is the same or different; when u represents 0 to 2, each R_{f} is the same or different;
the thermal base generator (C) comprises a compound represented by Formula (4) or an salt derivative thereof and/or a compound represented by Formula (5) and/or a compound represented by Formula (6): 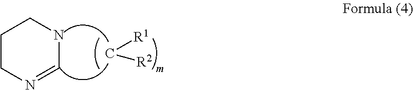
wherein:
m represents an integer of 2 to 6;
R¹ and R² independently represent a hydrogen atom, a C₁-C₈ alkyl group, a substituted or unsubstituted C₁-C₆ hydroxyalkyl group, or a C₂-C₁₂ dialkylamino group; 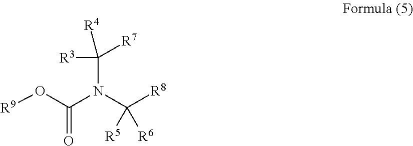
wherein:
R³, R⁴, R⁵ and R⁶ independently represent a hydrogen atom, a substituted or unsubstituted C₁-C₈ alkyl group, a substituted or unsubstituted C₃-C₈ cycloalkyl group, a substituted or unsubstituted C₁-C₈ alkoxy group, a substituted or unsubstituted C₂-C₈ alkenyl group, a substituted or unsubstituted C₂-C₈ alkynyl group, a substituted or unsubstituted aryl group, or a substituted or unsubstituted heterocyclic group;
R⁷ and R⁸ independently represent a hydrogen atom, a substituted or unsubstituted C₁-C₈ alkyl group, a substituted or unsubstituted C₃-C₈ cycloalkyl group, a substituted or unsubstituted C₁-C₈ alkoxy group, a substituted or unsubstituted C₂-C₈ alkenyl group, a substituted or unsubstituted C₂-C₈ alkynyl group, a substituted or unsubstituted aryl group, or a substituted or unsubstituted heterocyclic group, or R⁷ and R⁸ together form a substituted or unsubstituted monocyclic group, or R⁷ and R⁸ together form a substituted or unsubstituted polycyclic group;
R⁹ represents a substituted or unsubstituted C₁-C₁₂ alkyl group, a substituted or unsubstituted C₃-C₁₂ cycloalkyl group, a substituted or unsubstituted C₂-C₁₂ alkenyl group, a substituted or unsubstituted C₂-C₁₂ alkynyl group, an unsubstituted aryl group, an aryl group substituted with a C₁-C₃ alkyl group, an unsubstituted aralkyl, an aralkyl group substituted with a C₁-C₃ alkyl group or a substituted or unsubstituted heterocyclic group; the total carbon atom amount of R⁹ is below 12; 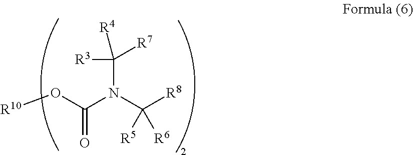
wherein:
R³, R⁴, R⁵, R⁶, R⁷ and R⁸ are as defined in Formula (5);
R¹⁰ represents a substituted or unsubstituted C₁-C₁₂ alkylene group, a substituted or unsubstituted C₃-C₁₂ cycloalkylene group, a substituted or unsubstituted C₂-C₁₂ alkenylene group, a substituted or unsubstituted C₂-C₁₂ alkynylene group, an unsubstituted arylene group, an arylene group substituted with a C₁-C₃ alkyl group, an unsubstituted aralkylene group, an aralkylene group substituted with a C₁-C₃ alkyl group or a substituted or unsubstituted heterocyclic group; the total carbon atom amount of R¹⁰ is below 12.

2. The photosensitive polysiloxane composition according to claim 1, wherein based on 1 mole of the total used amount of the monomers in the mixture, the used amount of the silane monomer (a-1) is from 0.01 mole to 0.2 moles; the used amount of the silane monomer (a-2) is from 0.01 mole to 0.4 moles; and the used amount of the silane monomer (a-3) is from 0.4 moles to 0.98 moles.

3. The photosensitive polysiloxane composition according to claim 1, wherein based on 100 parts by weight of the used amount of the polysiloxane (A), the used amount of the o-naphthoquinone diazide sulfonic acid ester (B) is from 1 part by weight to 30 parts by weight; the used amount of the thermal base generator (C) is from 0.05 parts by weight to 40 parts by weight; and the used amount of the solvent (D) is from 100 parts by weight to 1000 parts by weight.

4. The photosensitive polysiloxane composition according to claim 1, wherein the silane monomer (a-3) further comprises a silane monomer (a-3-1) represented by Formula (i)
Si(OR_{g})₄ Formula (i),
wherein:
R_{g} represents a hydrogen atom, a C₁-C₆ alkyl group, a C₁-C₆ acyl group, or a C₆-C₁₅ aryl group; and each R_{g} is the same or different.

5. The photosensitive polysiloxane composition according to claim 4, wherein based on 1 mole of the total used amount of the monomers in the mixture, the used amount of the silane monomer (a-3-1) is from 0.1 mole to 0.6 moles.

6. A method for forming a thin film on a substrate comprising applying the photosensitive polysiloxane composition according to claim 1 on the substrate.

7. The method according to claim 6, wherein based on 1 mole of the total used amount of the monomers in the mixture, the used amount of the silane monomer (a-1) is from 0.01 mole to 0.2 moles; the used amount of the silane monomer (a-2) is from 0.01 mole to 0.4 moles; and the used amount of the silane monomer (a-3) is from 0.4 moles to 0.98 moles.

8. The method according to claim 6, wherein based on 100 parts by weight of the used amount of the polysiloxane (A), the used amount of the o-naphthoquinone diazide sulfonic acid ester (B) is from 1 part by weight to 30 parts by weight; the used amount of the thermal base generator (C) is from 0.05 parts by weight to 40 parts by weight; and the used amount of the solvent (D) is from 100 parts by weight to 1000 parts by weight.

9. The method according to claim 6, wherein the silane monomer (a-3) further comprises a silane monomer (a-3-1) represented by Formula (i)
Si(OR_{g})₄ Formula (i),
wherein:
R_{g} represents a hydrogen atom, a C₁-C₆ alkyl group, a C₁-C₆ acyl group, or a C₆-C₁₅ aryl group; and each R_{g} is the same or different.

10. The method according to claim 9, wherein based on 1 mole of the total used amount of the monomers in the mixture, the used amount of the silane monomer (a-3-1) is from 0.1 mole to 0.6 moles.

11. A thin film on a substrate, which is manufactured by the method according to claim 6.

12. The thin film according to claim 11, wherein based on 1 mole of the total used amount of the monomers in the mixture, the used amount of the silane monomer (a-1) is from 0.01 mole to 0.2 moles; the used amount of the silane monomer (a-2) is from 0.01 mole to 0.4 moles; and the used amount of the silane monomer (a-3) is from 0.4 moles to 0.98 moles.

13. The thin film according to claim 11, wherein based on 100 parts by weight of the used amount of the polysiloxane (A), the used amount of the o-naphthoquinone diazide sulfonic acid ester (B) is from 1 part by weight to 30 parts by weight; the used amount of the thermal base generator (C) is from 0.05 parts by weight to 40 parts by weight; and the used amount of the solvent (D) is from 100 parts by weight to 1000 parts by weight.

14. The thin film according to claim 11, wherein the silane monomer (a-3) further comprises a silane monomer (a-3-1) represented by Formula (i)
Si(OR_{g})₄ Formula (i),
wherein:
R_{g} represents a hydrogen atom, a C₁-C₆ alkyl group, a C₁-C₆ acyl group, or a C₆-C₁₅ aryl group; and each R_{g} is the same or different.

15. The thin film according to claim 14, wherein based on 1 mole of the total used amount of the monomers in the mixture, the used amount of the silane monomer (a-3-1) is from 0.1 mole to 0.6 moles.

16. The thin film according to claim 11, wherein the thin film is a planarization film of a TFT substrate in a liquid crystal display element or organic light-emitting display device, an interlayer insulating film or an overcoat of a core material or a protective material in a waveguide.

17. A device comprising the thin film according to claim 11.

18. The device according to claim 17, wherein the thin film is a planarization film of a TFT substrate in a liquid crystal display element or organic light-emitting display device, an interlayer insulating film or an overcoat of a core material or a protective material in a waveguide.
